(19) United States
(12) Patent Application Publication
(10) Pub. No.: US 2005/0201573 A1
(43) Pub. Date: Sep. 15, 2005

(54) Musical instrument audio amplifier circuit and system for producing distortion effects

(76) Inventor: Mark Alistair Poletti, Wellington (NZ)

Correspondence Address: DANN, DORFMAN, HERRELL & SKILLMAN, 1601 MARKET STREET, SUITE 2400, PHILADELPHIA, PA, 19103-2307, US

(21) Appl. No.: 11/068,075

(22) Filed: Feb. 28, 2005

(30) Foreign Application Priority Data
Feb. 26, 2004 (NZ) 531397

(51) Int. Cl. G10H 1/00; H03F 21/00

(52) U.S. Cl. 381/118; 381/120

(57) ABSTRACT

A musical instrument amplifier circuit that can produce an output signal having a level of distortion that depends on the input signal. The amplifier circuit includes an amplifier arranged to receive the input signal and a filter following the amplifier that produces the output signal, wherein the output signal is fed back into the input signal so that the bandwidth of the amplifier circuit is modulated by the input signal. For example, the bandwidth of the amplifier circuit is wider at lower amplifier gains or input signal levels than at higher amplifier gains or input signal levels.

### FIELD OF THE INVENTION

The present invention relates to a musical instrument amplifier circuit and system. In particular, although not exclusively, the amplifier circuit and system may be utilised as a guitar amplifier, or within a guitar amplifier, to produce subjectively pleasing distortion effects.

### BACKGROUND TO THE INVENTION

Distortion effects have been used in guitar amplifiers since their development. Early amplifiers were built using valve (vacuum tube) technology, and originally distortion of these devices occurred by chance, as the high level guitar signal overloaded the preamplifier and/or power amplifier stages. However, the effect rapidly became an integral part of popular music styles such as blues and rock, and guitar amplifiers were soon designed specifically to allow overloading of the preamplifier or power amplifier.

With the development of transistors and integrated circuits, solid state guitar amplifiers have been developed, but the tube amplifier remains the more popular choice for the production of distortion effects [E Barbour: “The Cool Sound of Tubes”, IEEE Spectrum, pp 24-35, August 1998; E. K. Pritchard: “The Tube Sound and Tube Emulators”, dB, pp 22-30, July/August 1994]. Many reasons have been proposed for this preference, such as the tube plate current versus grid voltage characteristics, the asymmetric clipping that can occur in tube preamplifiers, the effect of the output transformer, the higher output impedance of tube amplifiers and the effects of valve rectifier power supplies.

A number of devices have been proposed that aim to replicate the sound of tube amplifiers using solid state devices or digital technology, examples of which are described in: U.S. Pat. Nos. 5,434,536, 5,636,284, 4,439,742, 4,405,832, and 5,789,689; and European Patent Nos. 0 663 720 and 0 662 752. Most of the devices described in these patents aim to produce the overload characteristics of vacuum tube amplifiers by simulating their characteristic curves or simulating their behaviour in particular circuits.

Another feature of valve amplifiers claimed to produce improved sound is the fact that valve power amplifiers use only moderate levels of feedback. Feedback linearises an amplifier, reducing the total harmonic distortion, up until the point where the amplifier output saturates, whereupon the output waveform becomes extremely distorted. There is thus a rapid transition from linear to non-linear behaviour with high feedback levels, and the resulting harmonic distortion contains a large number of high frequency harmonics, which are subjectively unpleasant [E Barbour: “The Cool Sound of Tubes”, IEEE Spectrum, pp 26, August 1998].

Valve amplifiers require an output transformer, and the complicated frequency response of the transformer means that high levels of feedback cannot be easily applied. Therefore, it may be argued that the valve amplifier can produce a more gradual overload than solid state amplifiers which employ very high levels of feedback. Some amplifier designs have even been developed to produce distortion without feedback being applied to the power amplifier, due to the presumed unpleasant sound quality such feedback produces. For example, U.S. Pat. No. 4,987,381 discloses a tube sound solid state amplifier comprising a closed loop transistor driver with linearising feedback that drives an open loop mosfet output stage. The feedback linearised driver is specifically operated so as to avoid clipping, which is said to be subjectively unpleasant. All clipping occurs in the open loop mosfet output stage.

Despite the belief that feedback is undesirable in the production of non-linear distortion, most commercial valve guitar amplifiers still use moderate levels of feedback around the power amplifier. Furthermore, valve power amplifier stages often distort at full volume, and the resulting sound is in many cases regarded as subjectively desirable.

It is an object of the present invention to provide a musical instrument amplifier circuit or system or both that can produce subjectively desirable distortion, or to at least provide the public with a useful choice.

### SUMMARY OF THE INVENTION

In a first aspect, the present invention broadly consists in a musical instrument amplifier circuit that can produce distortion comprising: an amplifier arranged to receive an input signal; and a filter following the amplifier that produces an output signal having a level of distortion that depends on the input signal, the output signal being fed back into the input signal so that the bandwidth of the amplifier circuit is modulated by the input signal.

Preferably, the bandwidth of the amplifier circuit is wider at lower amplifier gains or input signal levels than at higher amplifier gains or input signal levels. More specifically, the bandwidth of the amplifier circuit reduces as the amplifier is driven into saturation or is overloaded by the input signal. Preferably, the feedback of the output signal into the input signal is negative.

The amplifier circuit may, for example, have a sufficient bandwidth at low input signal levels to produce a substantially non-distorted output signal, the bandwidth reducing as the input signal level increases to overload the amplifier thereby producing an output signal with distortion that has reduced high frequency products.

By way of example, the amplifier of the amplifier circuit may be a non-linear waveshaper. Preferably, the non-linear waveshaper has a transfer characteristic that is monotonically increasing. Alternatively, the non-linear waveshaper may have a transfer characteristic that includes any one or more of the following features: signal limiting; negative slope at high input signal levels; and crossover distortion at high input signal levels.

Preferably, the filter of the amplifier circuit has at least a low pass characteristic for attenuating high frequency signals. Additionally, the filter may further comprise a high pass characteristic such that it has an overall bandpass characteristic. The filter may be implemented with first, second or higher order filters as desired.

Preferably, the filter causes the amplifier circuit to have a maximally flat frequency response with feedback at lower amplifier gains or input signal levels, and a reduced bandwidth at higher amplifier gains or input signal levels.

In one form, the musical instrument amplifier circuit may be implemented digitally and may be arranged to receive and output digitally sampled signals. For example, the amplifier, or more specifically the non-linear waveshaper, may be implemented by a non-linear function or a table look-up function with interpolation between values. Furthermore, the filter may be a digital filter, which could for example be constructed from a bilinear transformation of an analogue filter.

Preferably, the digital filter causes the amplifier circuit to have a maximally flat frequency response with feedback at lower amplifier gains or input signal levels, and a reduced bandwidth at higher amplifier gains or input signal levels.

In a second aspect, the present invention broadly consists in a musical instrument amplifier system that can produce distortion comprising: an equi-phase bandsplitter for separating an input signal into two or more separate frequency band signals; two or more musical instrument amplifier circuits each arranged to receive one of the frequency band signals, wherein each amplifier circuit comprises: an amplifier arranged to receive the frequency band signal; and a filter following the amplifier that produces an output signal having a level of distortion that depends on the frequency band signal, the output signal being fed back into the frequency band signal so that the bandwidth of the amplifier circuit is modulated by the frequency band signal; and a summing device arranged to recombine the output signals of the amplifier circuits into a single output signal.

Preferably, the amplifier system is arranged to reduce intermodulation distortion in the single output signal. More preferably, the amplifier system is also arranged to have a wide bandwidth at low input signal levels.

The amplifier system may, for example, be multiband with the equi-phase bandsplitter being arranged to separate the input signal into four separate frequency band signals, each of which is input to one of four amplifier circuits.

In one form, the amplifier system may be implemented digitally and may be configured to receive and output digitally sampled signals. For example, the equi-phase bandsplitter, musical instrument amplifier circuits, and summing device may be implemented digitally.

The musical instrument amplifier circuits of the amplifier system may also have any one or more of the features outlined in respect of the first aspect of the invention.

In a third aspect, the present invention broadly consists in a solid-state audio amplifier circuit comprising: an amplifier arranged to receive an audio input; and a filter, having at least a low pass characteristic, following the amplifier that produces an audio output, the audio output being fed back into the audio input thereby providing a wide bandwidth for clean sound at the audio output, the bandwidth reducing as the amplifier overloads to produce distorted sound with reduced high harmonics at the audio output.

The solid-state audio amplifier circuit may also have any one or more of the features outlined in respect of the first aspect of the invention.

In this specification and the accompanying claims, the term “circuit” is intended to cover any type of solid-state circuit implementation that utilises analog or digital components or both, and also extends, for example, to circuits that are fabricated into integrated circuit chips or those that are implemented partially or entirely in software (algorithms) running on an associated microprocessor or microcomputer.

The term ‘comprising’ as used in this specification and claims means ‘consisting at least in part of’, that is to say when interpreting statements in this specification and claims which include that term, the features, prefaced by that term in each statement, all need to be present but other features can also be present.

The invention consists in the foregoing and also envisages constructions of which the following gives examples only.

### BRIEF DESCRIPTION OF THE DRAWINGS

Preferred forms of the invention will be described by way of example only and with reference to the drawings, in which:

FIG. 1 shows a schematic block diagram of a preferred form musical instrument amplifier circuit;

FIG. 2 shows a plot of a typical transfer characteristic for a waveshaper used as the amplifier within the preferred form musical instrument amplifier circuit;

FIG. 3 shows a possible implementation of the musical instrument amplifier circuit, including a non-linear waveshaper, first order low pass filter, and feedback path;

FIG. 4 shows an alternative implementation of the musical instrument amplifier circuit that uses a second order low pass filter;

FIG. 5 shows another alternative implementation of the musical instrument amplifier circuit that uses a second order bandpass filter; and

FIG. 6 shows a possible implementation of a multiband musical instrument amplifier system, including an equi-phase bandsplitter, four musical instrument amplifier circuits as shown in FIG. 4, and a summing device.

### DETAILED DESCRIPTION OF PREFERRED FORMS

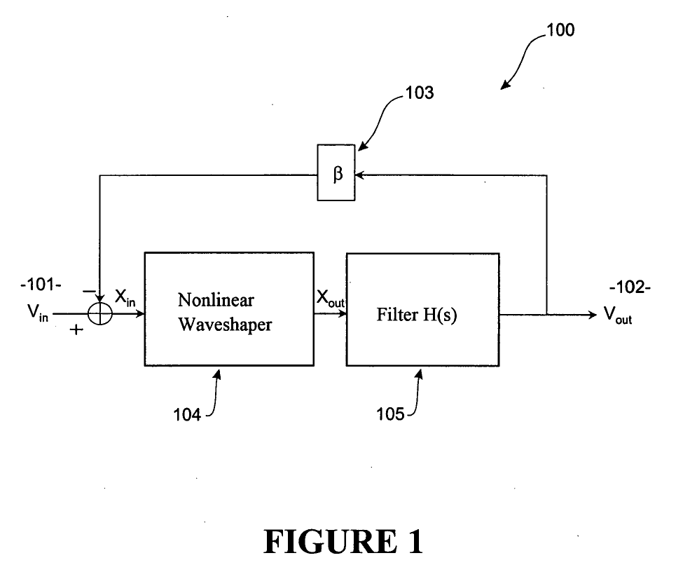

Referring to FIG. 1, the musical instrument amplifier circuit (or distortion circuit) 100 receives an input audio signal 101, from a guitar or other musical instrument for example, and produces an output signal 102, which may be played through speakers or transferred to further amplifier stages. The amplifier circuit 100 utilises feedback 103 around an amplifier device 104, for example a non-linear waveshaping circuit, to provide a wide bandwidth for clean sound, said bandwidth reducing when the waveshaping circuit overloads, producing a distortion sound with reduced high harmonics. The amplifier circuit 100 may be utilised as or within a guitar distortion system for example.

It is well known in the literature that feedback increases the bandwidth of an amplifier [Millman and Halkias, Integrated Electronics, McGraw-Hill, 1972]. For example, a voltage amplifier with a single dominant pole at frequency f₀, forward gain A, and voltage feedback factor β produces a cutoff frequency with feedback of (1+Aβ)f₀, an increase in bandwidth of (1+Aβ).

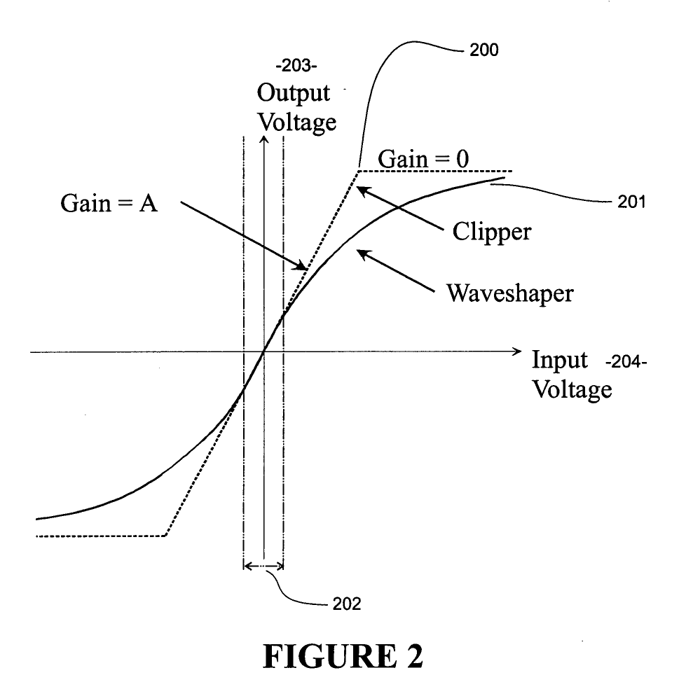

The non-linear waveshaper 104 has feedback 103 applied around it via a filter 105, which has a low pass characteristic, with feedback gain β. The output signal 102 is taken from the output of the filter 105. Referring to FIG. 2, the transfer characteristic curves are shown for a typical clipping amplifier 200 and a waveshaper 201. The waveshaper amplifier characteristic 201 is distinguished from the usual clipping amplifier characteristic 200 in that it produces a more gradual overload characteristic, with a smoother transition between linear and non-linear states. As shown, the small-signal gain of the waveshaper 104 varies with the voltage of the input signal 101. For low signal amplitudes the gain is equal to the derivative of the transfer curve 201 at zero, which is denoted A. Therefore at low signal levels the loop gain is Aβ.

The filter 105 may be any order, and may be a combination of high pass and low pass characteristics, to produce a variety of bandpass characteristics. However, the key requirement is that there be at least a single pole low pass filter in the filter response to attenuate high frequencies. The minimum filter is therefore first order low pass.

The cutoff frequency of the low pass filter is set relatively low, such that it would produce a low bandwidth if used without feedback. The effect of feedback is to boost the cutoff frequency such that the circuit has a wide bandwidth at low signal levels. For guitar signals, a low bandwidth is one that is typically below 5 kHz and a wide bandwidth typically exceeds 5 kHz. For example, with a cutoff frequency of f₀=2 kHz, and loop gain Aβ=10, the bandwidth of the amplifier circuit 100 at low input signals 101 is approximately 22 kHz. This reduces to near 2 kHz when the waveshaper 104 goes into saturation at higher input signal 101 levels.

Analysis of the generic amplifier circuit 100 of FIG. 1 follows. At low input signal 101 levels, the waveshaper 104 has gain A and the circuit operates in a linear fashion. The transfer function with feedback is

$$\frac{{V}_{out} ( s )}{{V}_{in} ( s )} = \frac{AH ( s )}{1 + A β H ( s )} \qquad 1$$

The low frequency gain, where H(s)=1, is A/(1+Aβ), which is the open loop gain divided by the feedback factor (1+Aβ).

If the input signal 101 level increases in amplitude, the waveshaper 104 starts to operate in the non-linear part of its transfer characteristic, for example outside the region 202 identified in FIG. 2. In these regions, the gain of the waveshaper 104 is reduced. Therefore the feedback loop gain is also reduced. This reduces the bandwidth of the system, attenuating any high frequency components in the signal at large amplitudes.

In the extreme case, if the waveshaper 104 is designed to go into full saturation at high input signal 101 levels, then at high input voltages there is no change in the output voltage 203 of the waveshaper 104 for changes in the input voltage 204, and A reduces to zero. The DC gain is then zero, and the bandwidth of the system reduces to ω₀. In this state, the low pass filter input voltage is constant and the filter output rises to equal this voltage with a rise time governed by its open loop cutoff frequency ω₀. However, as the input voltage swings back through zero volts, the bandwidth of the system increases to the maximum value again and the output waveform rapidly follows the input waveform. The bandwidth of the system is thus modulated by the input signal.

The primary subjective enhancement produced by the amplifier circuit 100 will now be outlined. At low input levels without distortion, the bandwidth is high, allowing the transmission of the complete guitar signal spectrum. This is subjectively desirable. At high input levels, the waveshaper 104 starts to distort the signal. This has two effects. Firstly, harmonic and intermodulation distortion are generated. These new frequency components are predominantly at high frequencies, and sound subjectively harsh. Secondly, however, the loop gain and hence the bandwidth are reduced at high signal amplitudes. This attenuates the new high frequency distortion products and reduces their harshness, producing a subjectively pleasing sound, which has a spectrum more similar to that of the undistorted guitar signal. The degree of attenuation depends on the order of the low pass component of the filter H(s).

The non-linear waveshaping network represents a simple form of distortion in which the transfer characteristic is monotonically increasing. However, more complicated forms of non-linearity may also be implemented utilising the circuit configuration of FIG. 1. For example, transfer characteristics may be implemented whose slopes become negative at large signal amplitudes. Circuitry that produces crossover distortion at high signal levels may also be implemented. It will also be appreciated that a standard clipping amplifier may be utilised in the amplifier circuit, although the resulting audio output signal will sound harsher. Other types of amplifiers may also be used in alternative forms of the amplifier circuit.

Various implementations of the amplifier circuit 100 will now be described. In particular, examples of the various forms of filter H(s) that can be utilised in the amplifier circuit will be explained. Following this, a multiband musical instrument amplifier system will be described that uses four of the amplifier circuits.

First Order Low Pass Filter

If H(s) is a first order low pass filter

$$\begin{matrix}H ( s ) = \frac{{ω}_{0}}{s + {ω}_{0}} \\ then & 2 \\ \frac{{V}_{out} ( s )}{{V}_{in} ( s )} = \frac{A {ω}_{0}}{s + ( 1 + A β ) {ω}_{0}} & 3\end{matrix}$$

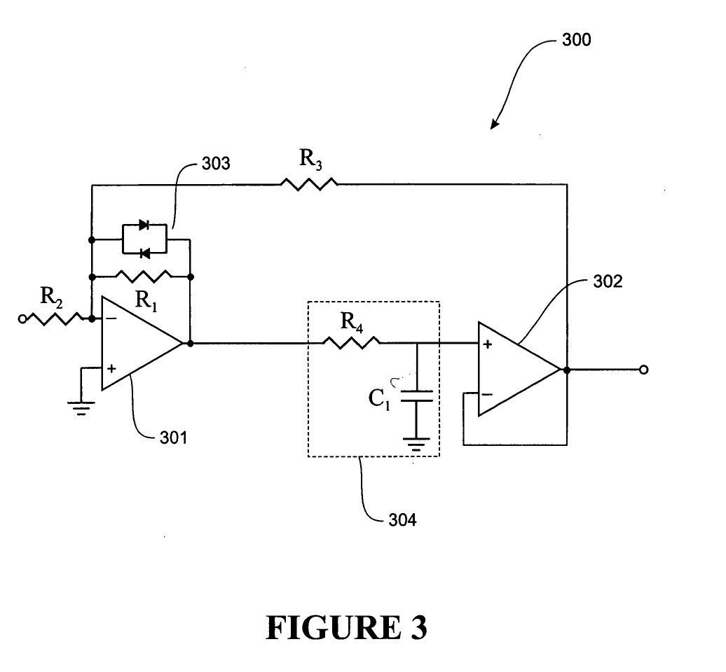

The low frequency gain is A/(1+Aβ) and the cutoff frequency with feedback is
ω_{fb}=(1+Aβ))ω₀ 4
The circuit configuration shown in FIG. 3 is an implementation of the musical instrument amplifier circuit that uses two operational amplifiers 301, 302, a diode waveshaper 303 and a first order RC low pass filter 304. The open loop forward gain is A=R₁/R₂ and the loop gain is Aβ=R₁/R₃. The diode waveshaper 303 is well known in the art [National Semiconductor Corporation, Audio/Radio Handbook, 1980].
Second Order Low Pass Filter

If H(s) is a second order low pass filter

$$H ( s ) = \frac{{ω}_{0}^{2}}{{s}^{2} + \frac{{ω}_{0}}{Q} s + {ω}_{0}^{2}} \qquad 5$$

then the linear transfer function at small input voltages with feedback is

$$\frac{{V}_{out} ( s )}{{V}_{in} ( s )} = \frac{A {ω}_{0}^{2}}{{s}^{2} + \frac{{ω}_{0}}{Q} s + ( 1 + A β ) {ω}_{0}^{2}} \qquad 6$$

The second order bandwidth with feedback is thus
ω_{fb}=ω₀\sqrt{+1+Aβ} 7
and the Q with feedback is
Q_{fb}=Q\sqrt{1+Aβ} 8

This means that for a given Q with feedback, the open loop Q must be

$$Q = \frac{{Q}_{fb}}{\sqrt{1 + A β}} \qquad 9$$

For example, a maximally flat frequency response (Q_{fb}=1/\sqrt{2}) requires an open loop Q of

$$Q = \frac{1}{\sqrt{2 ( 1 + A β )}} \qquad 10$$

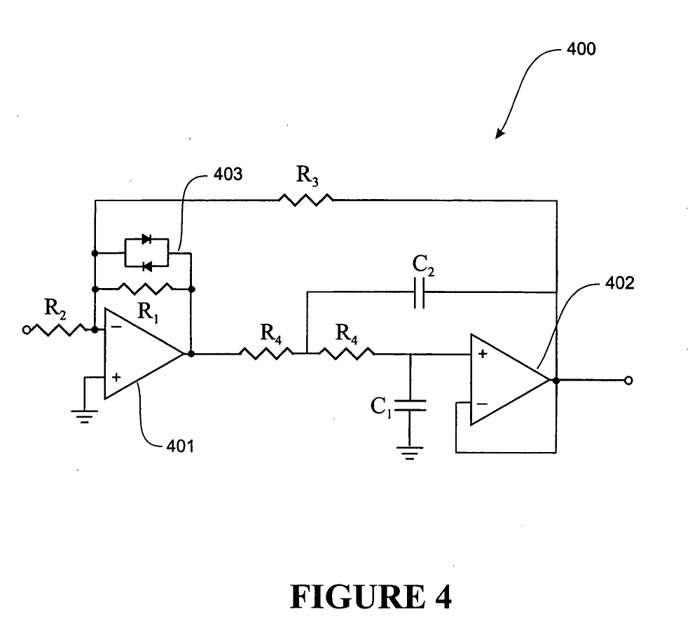

The circuit configuration 400 shown in FIG. 4 is an implementation of the musical instrument amplifier circuit that uses two operational amplifiers 401, 402, a diode waveshaper 403 and a second order low pass filter (components R₄ₛ, C₁ and C₂). The open loop forward gain is again A=R₁/R₂ and the loop gain Aβ=R₁/R₃.

The lowpass filter has cutoff frequency

$$\begin{matrix}{ω}_{0} = \frac{1}{{R}_{4} \sqrt{{C}_{1} {C}_{2}}} \\ and Q & 11 \\ Q = \frac{1}{2} \sqrt{\frac{{C}_{2}}{{C}_{1}}} & 12\end{matrix}$$

Hence the Q and cutoff frequency ω₀ can be independently controlled as required.

Second Order Bandpass Filter

The second order bandpass response is

$$H ( s ) = \frac{s {ω}_{0}}{{s}^{2} + \frac{{ω}_{0}}{Q} s + {ω}_{0}^{2}} \qquad 13$$

which has a midband gain of Q at ω=ω₀. With feedback the linear transfer function at small input voltages is

$$\frac{{V}_{out} ( s )}{{V}_{in} ( s )} = \frac{As {ω}_{0}}{{s}^{2} + s ( \frac{1}{Q} + A β ) {ω}_{0} + {ω}_{0}^{2}} \qquad 14$$

This is a bandpass filter with Q

$${Q}_{fb} = \frac{Q}{1 + A β Q} \qquad 15$$

and midband gain

$$G = \frac{AQ}{1 + A β Q} \qquad 16$$

which is the open loop gain AQ reduced by 1/(1+AβQ). This includes the series connection of a first order low pass filter and a first order high pass filter as a special case. Feedback both increases the high frequency cutoff frequency and reduces the low frequency cutoff frequency, extending the bandpass filter frequency range in both directions.

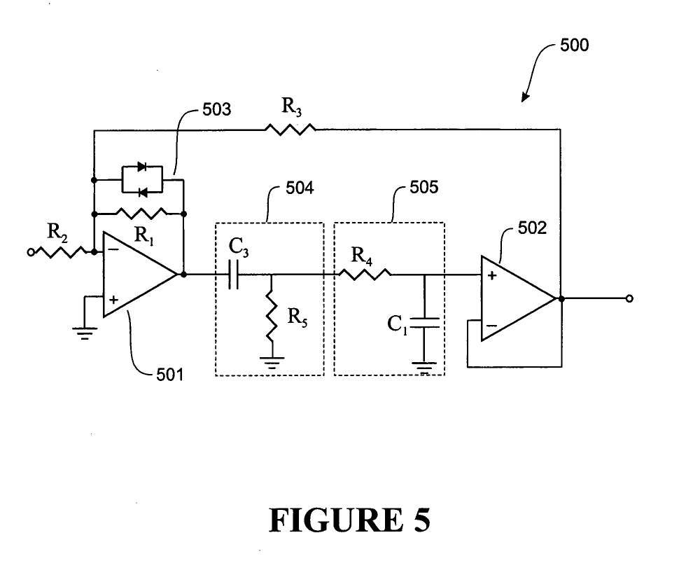

The circuit configuration 500 in FIG. 5 is an implementation of the musical instrument amplifier circuit that uses two operational amplifiers 501, 502, a diode waveshaper 503 and a series connection of a first order RC high pass filter 504 (consisting of R₅ and C₃) and low pass filter 505 (consisting of R₄ and C₁), where for typical operation the impedances of R₄ and C, are greater than those of R₅ and C₃. The cutoff frequencies are then approximately ω_{L}=1/(R₄C₁) and ω_{H}=1/(R₅C₃).

The bandpass form of the musical instrument amplifier circuit is useful in that it reduces the level of low frequency sounds that can occur when the low pass filter cutoff frequency is very low.

Higher Order Filters

Other implementations of the musical instrument amplifier circuit are possible, such as a first order high pass filter followed by a second order low pass filter. Filter orders higher than second may also be used provided that the circuit remains stable, as will be understood by those skilled in the art.

Digital Implementation

The musical instrument amplifier circuit 100, which produces distortion effects, may also be implemented in a digital sampled form. For example, the input signal may be sampled at sample rate fₛ Hertz, which is sufficiently high to accommodate the bandwidth of the distorted signal. It is well known that non-linear processing produces output frequencies that do not exist in the input signal. These frequencies consist of high frequency harmonics of the input frequencies together with low and high frequency intermodulation frequencies. Therefore, the sample rate for a non-linear system must be higher than that required for linear audio processing of the same signal [M. C. Jeruchim, P. Balaban and K. S. Shanmugan, Simulation of Communication Systems, Plenum Press, 1992].

The non-linear waveshaper may be implemented as either an analytic function or by using a table lookup with interpolation between the output values. A useful analytic function is [M. C. Jeruchim, P. Balaban and K. S. Shanmugan, Simulation of Communication Systems, Plenum Press, 1992]

$$y ( n ) = f ( x ( n ) ) = \frac{Lsgn ( x ( n ) )}{{[ 1 + {( \frac{l}{\vert x ( n ) \vert} )}^{s} ]}^{\frac{1}{s}}} \qquad 17$$

where:
x(n) is the numerical value of the nth sample of the input signal,
l is the input level at which non-linear waveshaping starts to occur (for |x|<l, the gain is approximately 1),
L is the asymptotic output level, and
s is the shape parameter that governs the response of the waveshaper

The lowpass filter is implemented using a bilinear transformation of the first or second order low pass filters in equations 2 and 5 above. This technique is also well known in the art.

Multiband Musical Instrument Amplifier System

In some guitar distortion systems, the input signal is split into multiple independent frequency bands, each band is individually distorted, and the distorted signals are recombined to produce a single output. For example, C. Anderton, “Four fuzzes in one with active EQ, Guitar Player, pp 37-46, June 1984 discloses a four band system using standard filters. M. Poletti, “An improved guitar preamplifier system with controllable distortion”, NZ Patent No. 329119, 6 Nov. 1997, which is incorporated herein by reference, discloses an improvement on the Quadrafuzz implementation, where equiphase cross-over filters are used to produce a constant sum response, and cross mixing is disclosed to allow control of intermodulation between frequency bands.

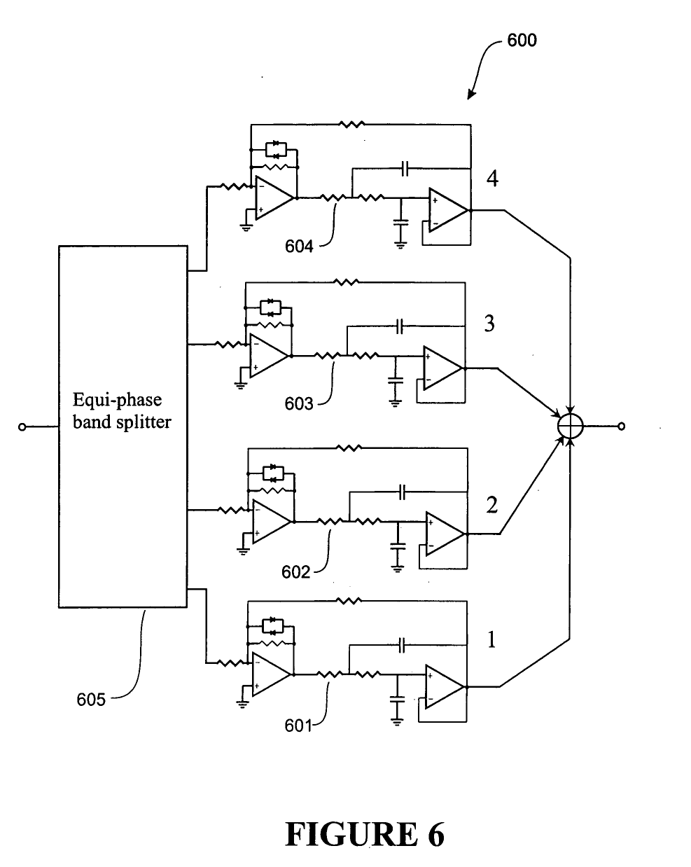

The feedback enhanced musical instrument amplifier circuits (distortion circuits) disclosed herein may be used in multiband distortion systems to provide wider bandwidths at low gain settings. FIG. 6 shows a possible circuit configuration 600 for a multiband system that uses distortion circuits 601-604 of the type shown in FIG. 4. The equi-phase bandsplitter 605 is implemented as shown in NZ 329119, FIG. 6. The four distortion circuits 601-604 may use the same lowpass filter characteristics to maintain identical phase responses, or if this is not judged to be important, may use cutoff frequencies that are related to the frequency range over which they operate. For example, if channel 1 is the lowest frequency range and channel 4 the highest, then the channel 1 filter has the lowest cutoff frequency and channel 4 has the highest.

It will be appreciated that distortion circuits that use first order low pass filters, second order bandpass filters or higher order filters may be utilised in alternative forms of the multiband system.

The multiband system may also be implemented digitally. For example, NZ 329119 discloses a digital implementation of the equi-phase bandsplitter and each of the distortion circuits may be implemented digitally as previously described. More specifically, the analytical function of equation 17 could be utilised to implement the non-linear waveshaper of the distortion circuit, while the filter of the distortion circuit may be implemented digitally using a bilinear transformation. This digital form of the feedback enhanced distortion algorithm may be included in the multiband system to provide improved frequency response at low signal levels.

The musical instrument amplifier circuit and system configurations described provide an advantage in that they utilise feedback with solid-state components to produce a subjectively desirable distortion effect. It will be appreciated that the solid-state circuits and systems may be implemented in a variety of ways. For example, they may be implemented using analog or digital components or both. Alternatively, the circuits and systems may be fabricated into an integrated circuit chip or may be implemented partially or entirely in software (algorithms) running on an associated microprocessor or microcomputer.

The foregoing description of the invention includes preferred forms thereof. Modifications may be made thereto without departing from the scope of the invention as defined by the accompanying claims.

1. A musical instrument amplifier circuit that can produce distortion comprising:
an amplifier arranged to receive an input signal; and
a filter following the amplifier that produces an output signal having a level of distortion that depends on the input signal, the output signal being fed back into the input signal so that the bandwidth of the amplifier circuit is modulated by the input signal.

2. A musical instrument amplifier circuit according to claim 1, wherein the bandwidth of the amplifier circuit is wider at lower amplifier gains or input signal levels than at higher amplifier gains or input signal levels.

3. A musical instrument amplifier circuit according to claim 1, wherein the bandwidth of the amplifier circuit reduces as the amplifier is driven into saturation or is overloaded by the input signal.

4. A musical instrument amplifier circuit according to claim 1, having a sufficient bandwidth at low input signal levels to produce a substantially non-distorted output signal, the bandwidth reducing as the input signal level increases to overload the amplifier thereby producing an output signal with distortion that has reduced high frequency products.

5. A musical instrument amplifier circuit according to claim 1, wherein the feedback of the output signal into the input signal is negative.

6. A musical instrument amplifier circuit according to claim 1, wherein the amplifier is a non-linear waveshaper.

7. A musical instrument amplifier circuit according to claim 6, wherein the non-linear waveshaper has a transfer characteristic that is monotonically increasing.

8. A musical instrument amplifier circuit according to claim 6, wherein the non-linear waveshaper has a transfer characteristic that comprises any one or more of the following features: signal limiting; negative slope at high input signal levels; and crossover distortion at high input signal levels.

9. A musical instrument amplifier circuit according to claim 1, wherein the filter has at least a low pass characteristic for attenuating high frequency signals.

10. A musical instrument amplifier circuit according to claim 9, wherein the filter further comprises a high pass characteristic such that it has an overall bandpass characteristic.

11. A musical instrument amplifier circuit according to claim 1, wherein the filter causes the amplifier circuit to have a maximally flat frequency response with feedback at lower amplifier gains or input signal levels, and a reduced bandwidth at higher amplifier gains or input signal levels.

12. A musical instrument amplifier circuit according to claim 1, which is implemented digitally and which is arranged to receive and output digitally sampled signals.

13. A musical instrument amplifier circuit according to claim 12, wherein the amplifier of the amplifier circuit is implemented digitally by a non-linear function or a table look-up function and the filter of the amplifier circuit is a digital filter.

14. A musical instrument amplifier circuit according to claim 13, wherein the digital filter causes the amplifier circuit to have a maximally flat frequency response with feedback at lower amplifier gains or input signal levels, and a reduced bandwidth at higher amplifier gains or input signal levels.

15. A musical instrument amplifier system that can produce distortion comprising:
an equi-phase bandsplitter for separating an input signal into two or more separate frequency band signals;
two or more musical instrument amplifier circuits each arranged to receive one of the frequency band signals, wherein each amplifier circuit comprises: an amplifier arranged to receive the frequency band signal; and a filter following the amplifier that produces an output signal having a level of distortion that depends on the frequency band signal, the output signal being fed back into the frequency band signal so that the bandwidth of the amplifier circuit is modulated by the frequency band signal; and
a summing device arranged to recombine the output signals of the amplifier circuits into a single output signal.

16. A musical instrument amplifier system according to claim 15, wherein the bandwidth of the amplifier circuits is wider at lower amplifier gains or frequency band signal levels than at higher amplifier gains or frequency band signal levels.

17. A musical instrument amplifier system according to claim 15, wherein the bandwidth of each of the amplifier circuits reduces as the amplifier is driven into saturation or is overloaded by the frequency band signal.

18. A musical instrument amplifier system according to claim 15, wherein each amplifier circuit has a sufficient bandwidth at low frequency band signal levels to produce a substantially non-distorted output signal, the bandwidth reducing as the frequency band signal level increases to overload the amplifier thereby producing an output signal with distortion that has reduced high frequency products.

19. A musical instrument amplifier system according to claim 15, arranged to reduce intermodulation distortion in the single output signal.

20. A musical instrument amplifier system according to claim 15, wherein the feedback used in each of the amplifier circuits is negative.

21. A musical instrument amplifier system according to claim 15, wherein the amplifier of each of the amplifier circuits is a non-linear waveshaper.

22. A musical instrument amplifier system according to claim 15, wherein the filter of each of the amplifier circuits has at least a low pass characteristic for attenuating high frequency signals.

23. A musical instrument amplifier system according to claim 22, wherein the filter of each of the amplifier circuits further comprises a high pass characteristic such that it has an overall bandpass characteristic.

24. A musical instrument amplifier system according to claim 15, wherein the filter of each of the amplifier circuits causes its respective amplifier circuit to have a maximally flat frequency response with feedback at lower amplifier gains or frequency band signal levels, and a reduced bandwidth at higher amplifier gains or frequency band signal levels.

25. A musical instrument amplifier system according to claim 15, which is implemented digitally.

26. A musical instrument amplifier system according to claim 15, wherein the system is multiband with the equi-phase bandsplitter being arranged to separate the input signal into four separate frequency band signals, each of which is input to one of four amplifier circuits.

27. A solid-state audio amplifier circuit comprising:
an amplifier arranged to receive an audio input; and
a filter, having at least a low pass characteristic, following the amplifier that produces an audio output, the audio output being fed back into the audio input thereby providing a wide bandwidth for clean sound at the audio output, the bandwidth reducing as the amplifier overloads to produce distorted sound with reduced high harmonics at the audio output.
